(19) United States
(12) Patent Application Publication
(10) Pub. No.: US 2024/0181569 A1
(43) Pub. Date: Jun. 6, 2024

(54) FRACTAL METALLIC NANOSTRUCTURE AND METHOD OF SYNTHESIS OF FRACTAL METALLIC NANOSTRUCTURE

(71) Applicant: Qatar Foundation for Education, Science and Community Development, Doha (QA)

(72) Inventors: Hicham Hamoudi, Doha (QA); Sara Iyad Mohd Saleh Ahmad, Doha (QA)

(21) Appl. No.: 18/385,560

(22) Filed: Oct. 31, 2023

Related U.S. Application Data
(60) Provisional application No. 63/421,341, filed on Nov. 1, 2022.

(51) Int. Cl. B23K 26/362; B33Y 40/20; B33Y 80/00

(52) U.S. Cl. CPC B23K 26/362; B33Y 40/20; B33Y 80/00

(57) ABSTRACT

A method for synthesis of fractal metallic nanostructure is provided. The method includes applying electron-beam irradiation directly on a metal-containing carbon nanosheet. Moreover, the Disclosed Invention relates to a novel method for the direct synthesis and control of fractal growth of metallic nanostructures on hybrid self-assembled metal/carbon nanosheets using electron-beam irradiation. In particular, the nanosheet is the source or the metallic precursor for the fractal nanostructure as well as the substrate on which the fractal formation takes place. In addition, the irradiation-induced interactions between the electron-beam and the carbon-based nanosheet enables the patterning and carving of the nanosheet with different designs of various complexities to eventually control the path and route of the irradiation induced nucleation and growth of the metallic fractal morphology.

### CROSS REFERENCE TO RELATED APPLICATIONS

This application claims the benefit of U.S. Provisional Application No. 63/421,341 filed Nov. 1, 2022, which is incorporated herein by reference in its entirety.

### BACKGROUND

Nature and natural systems are abundant with fractal scaling patterns more than most people acknowledge. From the branching in trees and the splitting of rivers to the pulmonary vessels and vascular system, to the foam on a latte cup or the shape of a winter snowflake, fractal shapes are characterized as complex patterns with detailed geometrical structures that are self-similar across different scales. Despite their abundance, it was not until the 1970's when Mandelbrot recognized fractal geometry and coined the term “fractal” which is a Latin word for irregular or broken.

The synthesis of metallic fractal nanostructures has been studied and reported via several synthesis methods including solvothermal and electrochemical processes, electroless metal deposition, irradiation methods including UV, microwave, gamma, and electron beam irradiations. However, most of the techniques require complex setups and mandate the use of organic solvents, surfactants, and templates, and have little to no control over the direction and the path at which the growth of the metallic fractal structures occurs. Meanwhile, the time required for the formation of the fractal nanostructures can range from several minutes to several hours. Therefore, a more efficient and simple method of synthesis of fractal metallic nanostructure is desired.

### SUMMARY

According to one non-limiting aspect of the present disclosure, an exemplary embodiment of a method for synthesis of fractal metallic nanostructure is provided. In one embodiment, the method includes applying electron-beam irradiation directly on a metal-containing carbon nanosheet.

Additional features and advantages are described in, and will be apparent from, the following Detailed Description and the Figures. The features and advantages described herein are not all-inclusive and, in particular, many additional features and advantages will be apparent to one of ordinary skill in the art in view of the figures and description. In addition, any particular embodiment does not have to have all of the advantages listed herein and it is expressly contemplated to claim individual advantageous embodiments separately. Moreover, it should be noted that the language used in the specification has been selected principally for readability and instructional purposes, and not to limit the scope of the inventive subject matter.

### BRIEF DESCRIPTION OF THE FIGURES

FIGS. 1A-F are a sequence of TEM images showing metallic fractal nanostructures formation and growth path on the carbon-based nanosheet starting with (a) the patterned design to (e) the expansion of the fractal nanostructure throughout the exposed nanosheet to the electron beam, according to an example embodiment of the present disclosure.

FIGS. 2A-C are a sequence of patterning the hybrid metal/carbon-based nanosheet with different designs to control the growth path of the fractal metallic nanostructures into (a) circular, (b) linear, and (c) complex morphologies, according to an example embodiment of the present disclosure.

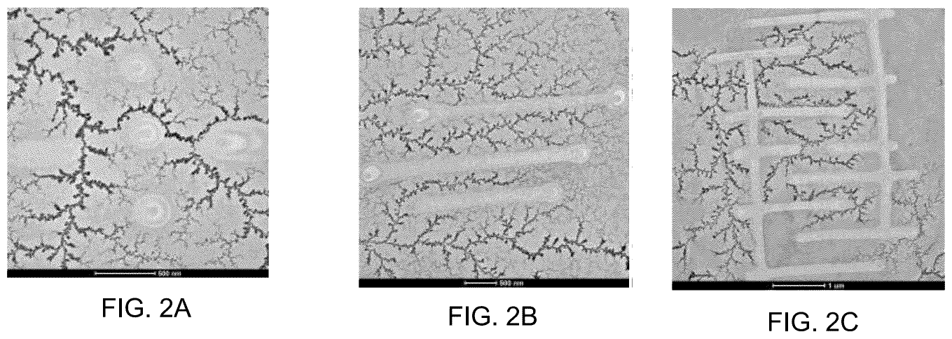

### DETAILED DESCRIPTION

The present disclosure generally relates to a fractal metallic nanostructure and a method of synthesis of fractal metallic nanostructure.

In this present disclosure, a method for the synthesis of fractal metallic nanostructures directly on carbon-thiol based nanosheets using electron-beam irradiation is provided. The carbon-based nanosheets are built using the self-assembled molecular monolayers (SAMs) concept where metallic atoms act as the mediators connecting the carbon-thiol monolayers together. Thus, the metallic precursor for the fractal formation is embedded in the carbon-based nanosheet during the initial building block process. Upon irradiating the sheet with the electron-beam, metallic fractal nanostructures with high yield and good uniformity immediately form covering the irradiated area. Initially, the electron-beam is used to carve and create different patterns on the carbon-based nanosheet with varying complexities. Depending on these carved patterns, the growth path of the fractal metallic nanostructures can be controlled to produce linear, circular, or blocking structures. The electron-beam induced metallic nano-fractals are unique in every instance and the integration between those fractals and the carbon nanosheet its grown on enables the construction of a new generation of miniaturized electrical components for electronic systems depending on the electronics structure of the molecules and the nature of the metallic nanofractals. The designs using this technique are suitable for projected applications in electrical circuits for human implants, Rectennas solar cells, fractal antennas, flexible and molecular electronics, and as unique identifiers in supply-chains thanks to their unique unclonable patterns.

The Disclosed Invention proposes a method that utilizes electron-beam irradiation for the direct synthesis of metallic fractal nanostructures with fine control over the fractal growth path onto two-dimensional carbon-based molecular nanosheets. The hybrid metal/carbon-based nanosheets are synthesized by a simple 3D printing approach. In this 3D printing approach, the carbon-based molecular monolayers are joined together by metallic atoms creating a nanosheet that consists of a periodic and continuous carbon-metal multilayer structure. Thus, the metallic precursor for the fractal formation is embedded in the carbon-based nanosheet during the initial building block process. This allows for the electron beam-activated nucleation and growth of the metallic nanoparticles (NPs) and their simultaneous diffusion and growth into fractal morphologies directly on the carbon-based nanosheets. Moreover, the electron-beam can be used to carve and create different paths on the carbon-based nanosheet with varying complexities. Depending on these carved paths, the growth path of the fractal metallic nanostructures can be controlled to produce linear, circular, or blocking structures.

The incorporation of the grown metallic fractal nanostructures onto the 2D organic molecular carbon-based nanosheets enables not only the construction of conductive nanostructures, e.g., metallic electrodes, but other complete electronic circuit components such as diodes, capacitors, transistors, etc., enabling the assembly of smaller electronic circuits than those achieved by the conventional solid-state semiconductor technology, which is expected to reach its miniaturization limits soon. The Disclosed Invention's method provides a unique versatile approach for the synthesis of metallic fractal nanostructures along with its direct integration on carbon nanosheets for the fabrication of the next-generation flexible and molecular electronics, thus forecasting huge potential in applications such as energy conversion, rectenna technologies, sensors and detectors, catalysis, plasmonics, and biomedical technologies, among others.

The present disclosure discloses a novel method/technology where electron beam is merely utilized as the source to induce the nucleation of metallic atoms, that are inherently embedded in a carbon-based nanosheet, and its growth into metallic fractal nanostructures on the carbon-based nanosheet itself. In particular, the nanosheet is both the source of the metallic precursor for the fractal nanostructures as well as the substrate on which the fractal formation takes place. Furthermore, the irradiation-induced interactions between the electron-beam and the carbon-based nanosheet enabled us to pattern and carve the nanosheet with different designs of various complexities prior to the fractal formation, to eventually control the path and route of growth of the metallic fractal morphology. The Disclosed Invention envisages the use of the electron-beam and the hybrid metal/carbon nanosheet to locally modify and control the growth of the metallic fractal nanostructures and directly create complex nano-circuit components in a matter of seconds, enabling new product paradigms that are simply not possible to envisage with conventional silicon-based semiconductors.

Furthermore, compared to other conventional technologies for the synthesis of fractal metallic nanostructures, the disclosed process of controlled direct fractal metal growth is template free, solvent free, surfactants and chemicals free, does not require any subsequent steps to create or transform the metallic nanofractals, and is environmentally green. In the present disclosure, the growth of the metallic nanofractals and the control of the fractals' path is done chemical-free using the electron-beam only. In fact, although the growth of nanoscale fractals has been observed previously, to the best of inventor knowledge, tracking, and directing the spatial nanofractal path has not been achieved thus far.

### Experimental Example

As previously noted, the Disclosed Invention describes a direct electron-irradiation based method for the synthesis of metallic fractal nanostructures with control over the fractal's growth path, along with its direct integration onto carbon-based nanosheets for the fabrication of the next-generation flexible and molecular electronics. The Disclosed Invention compares to other fractal nanostructure synthesis routes in: (i) utilizing electron-beam irradiation of hybrid metal/carbon-based nanosheets synthesized based on the molecular self-assembly concept using a 3D printing approach, (ii) the metal precursor for the fractal nanostructures is embedded in the hybrid metal/carbon-based nanosheets during the initial synthesis, thus the nanosheet acts as both the substrate and the active material on which the fractal formation is to take place, as well as the source of the metallic fractals to be formed, (iii) the growth path of the metallic fractal nanostructures can be controlled and directed using the electron beam irradiation, (iv) the incorporation of the grown metallic fractal nanostructures onto the 2D organic molecular carbon-based nanosheet enables the assembly of nanoscale electronic circuits for the next generation flexible and molecular electronics applications.

In the Disclosed Invention, the electron-beam induced metallic fractal nanostructures formation on 2D carbon-based nanosheets occurs in two steps: (1) the use a high electron-dose irradiation beam to create and carve any desired pattern on the 2D nanosheet, (2) the use of a low electron-dose irradiation beam to induce the formation and growth of metallic fractal nanostructures on which its growth path depends on the created patterns in step (1). Below are described the experimental results of the method in the Disclosed Invention, which includes the patterning of the 2D carbon-based nanosheet and the simultaneous synthesis and integration of the fractal metallic nanostructures.

During experimentation, a 3D printing method was used to synthesize the hybrid metal/carbon-based nanosheet using aromatic molecules and silver (Ag) as the carbon source and the metal precursor, respectively. The nanosheet was then placed directly on a transmission electron microscope (TEM) Cu grid and inserted in the TEM chamber where the electron irradiation took place. To begin with, a high-dose electron beam is used to carve and create different designs and paths on the carbon-based nanosheet with varying complexities.

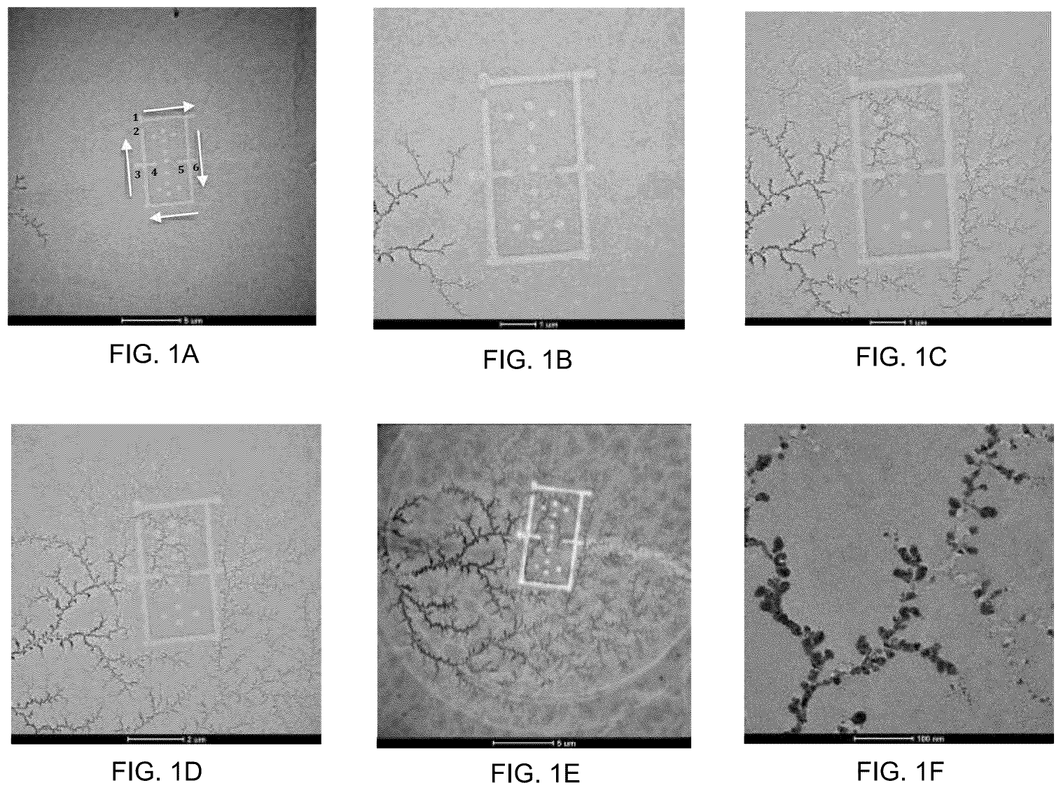

FIGS. 1A-E show a sequence of TEM images showing the metallic fractal nanostructures formation and growth path on the carbon-based nanosheet. Specifically, FIG. 1A shows a fractal trap pattern constructed to investigate the control of the metallic fractal nanostructures. The fractal trap consisted of straight lines making a rectangle and several dot-like features inside. Initially, the high-dose electron beam was focused on point 1 and moved along the yellow arrows as indicated in FIG. 1A to make the rectangle. However, the last line was not fully closed or attached to the starting point, see point 2 in FIG. 1A, in an aim to maintain an entrance for the metallic fractals and guide its growth into the rectangle area. After that, the electron beam was blanked in order to prevent any unwanted irradiation induced interactions with the nanosheet. In a similar process, the two shorter lines on the two sides of the rectangle were fabricated by focusing the blanked beam on point 3, un-blanking it and moving it to point 4, followed by blanking the beam and moving it to point 5, un-blanking it, and moving it to point 6, see FIG. 1A. Next, the electron beam was moved inside the rectangle to the desired coordinates and the dot-like features where fabricated simply by un-blanking the electron-beam on the desired spot on the sheet. The process was repeated until the desired pattern was created.

Once the desired pattern was achieved, both the magnification and electron-dose were reduced to allow the entire surrounding area to be affected by the irradiated electron beam and the formation of the metallic dendrites immediately commenced. The irradiation-induced nano-metallic fractals consist of long central metallic backbones and sharp secondary branches that exhibit good symmetry and self-similarity. The Disclosed Invention is based on the irradiation induced nucleation of metallic NPs and its irradiation-induced electric-field diffusion and growth in a fractal morphology. The fractal nanostructures path can be traced from FIGS. 1A to 1E. Eventually, the entire nanosheet was covered with fractal metallic nanostructures except the initially high electron-dose patterned areas. FIG. 1F shows a magnified image of the fractal nanostructure confirming the nanometric nature and size of the formed fractal NPs.

To further confirm the spatial control over the formed fractals, and the versatile nature of the fractal nanostructures synthesized with this technique, the nanosheet was patterned with several designs using the same process discussed above. Depending on these patterns, the growth path of the fractal metallic nanostructures was controlled to produce either linear, circular, or blocking structures, in electronic circuit design.

As seen in FIGS. 1A-E and 2A-C, the high-dose patterned areas are lighter in color than the surrounding nonpatterned areas. This is directly related to the expelling of the metal ions (Ag in this case) upon exposure to a sudden high dose electron beam irradiation and thus a lower metal ion concentration in the irradiated regions compared to the surrounding areas. In addition, exposing a 2D nano-thin carbon-based nanosheet to the irradiation of a high-energy electron beam creates “atomic chaos” in the irradiated regions leading to bond distortions, a high density of structural defects, and possible cross linking. Thus, the lack of metal ions and the high structural chaos inside the irradiated regions prevent the fractal formation inside those regions, in a way, controlling the path of the metallic nanofractals.

The present disclosure also relates to the direct synthesis and control of metallic fractal nanostructures on organic 2D hybrid metal/carbon-based organic nanosheets using electron-beam irradiation. The created metallic fractal nanostructures are incorporated directly onto the organic carbon-based nanosheets, which act as both the metal precursor and the substrate on which the fractal growth occurs. Furthermore, the present disclosure discloses a method to direct and control the fractal nanostructure path through patterning the carbon-based sheet prior to the fractal nanostructures formation and growth. Experiments are underway to develop different patterning designs for further control on the metallic fractals directed formation and growth, and to explore the fabrication of electronic circuit designs through the integration of the fractal metallic nanostructures and the underlying patterned nanosheets.

The method described in the present disclosure has the following advantages over existing processes for metallic fractal nanostructures formation and growth:
Direct fabrication of metallic fractal nanostructures on organic carbon-based nanosheets.
The inclusion of the metallic precursor in the carbon-based sheet is done during the same synthesis process of the sheet itself.
A simple electron-beam irradiation process for both the patterning of the carbon-based nanosheet and the formation of the metallic fractal nanostructures.
The ability to control the growth path of the metallic nanofractals.
Extremely fast metallic deposition/printing/writing of fractal nanostructures in a matter of seconds.
Template free, solvent free, surfactants and chemicals free, does not require any subsequent steps to create or transform the metallic nanofractals, and is environmentally green.
Nanoscale resolution formation of metallic fractals directly on carbon-based nanosheets.
The integration of the metallic fractal nanostructures and the carbon-based nanosheet provides the ability to assemble electronic devices in a molecular level and a bottom-up manner.
Resolving the connectivity challenge between functional molecules and metallic electrodes in molecular and flexible electronics since the carbon-based molecules are already bonded and connected with the metallic fractal nanostructures during the nanosheet synthesis.
High-throughput creation of nanoscale fractal nanostructures with high-precision.
Electron beam patterning inside the TEM allows for the in-situ fabrication and characterization in the same system at the same time.
Providing an easy path to integrate the electronics with the biological network such as the neuron-human for the next generation of the bioelectronics devices.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A method of synthesis of fractal metallic nanostructure, comprising:
applying electron-beam irradiation directly on a metal-containing carbon nanosheet.

2. The method of claim 1, wherein the metal-containing carbon nanosheet includes a carbon-thiol based nanosheet.

3. The method of claim 1, wherein the metal-containing carbon nanosheet is prepared by self-assembled molecular monolayers or by 3D printed self-assembled molecular method.

4. The method of claim 1, wherein the electron-beam is used to form one or more patterns on the carbon-based nanosheet.
